(19) United States
(12) Patent Application Publication
(10) Pub. No.: US 2012/0032186 A1
(43) Pub. Date: Feb. 9, 2012

(54) WHITE ORGANIC LIGHT EMITTING DEVICE

(75) Inventors: Jeong Ik LEE, Suwon-si (KR); Hye Yong CHU, Daejeon (KR); Lee Mi DO, Daejeon (KR); Sang Hee PARK, Daejeon (KR); Chi Sun HWANG, Daejeon (KR); Yong Suk YANG, Daejeon (KR); Sung Mook CHUNG, Suwon-si (KR)

(73) Assignee: ELECTRONICS AND TELECOMMUNICATIONS RESEARCH INSTITUTE, Daejeon (KR)

(21) Appl. No.: 13/239,810

(22) Filed: Sep. 22, 2011

Related U.S. Application Data
(62) Division of application No. 11/522,642, filed on Sep. 18, 2006.

(30) Foreign Application Priority Data
Dec. 6, 2005 (KR) 10-2005-0118184
May 17, 2006 (KR) 10-2006-0044065

(51) Int. Cl. H01L 33/02

(52) U.S. Cl. 257/76; 257/E33.013

(57) ABSTRACT

Provided is a white organic light emitting device (OLED), including: a first electrode formed on a substrate; a hole transport layer formed on the first electrode; an emission layer formed on the hole transport layer; an electron transport layer formed on the emission layer; and an color control layer formed on at least one of the hole transport layer, the emission layer and the electron transport layer, and emitting green and/or red by energy transfer from the emission layer. The white OLED emits red, green and blue light with high efficiency, has excellent color reproducibility and a high color reproduction index.

### CROSS-REFERENCE TO RELATED APPLICATION

This application claims priority to and the benefit of Korean Patent Application Nos. 2005-118184, filed on Dec. 6, 2005 and 2006-44065, filed on May 17, 2006, the disclosures of which are incorporated herein by reference in their entirety.

### BACKGROUND

1. Field of the Invention

The present invention relates to a white organic light emitting device (OLED), and more particularly, to a white OLED whose color purity and efficiency are enhanced using a simple process.

2. Discussion of Related Art

Recent development trends in the display industry are the product of the ongoing pursuit of small, lightweight and slim displays employing a thin film, and ever present demand for high resolution. In the drive to create a next generation display that can satisfy consumer demand, OLED technology has been singled out among existing device manufacturing technologies and made the focus of widespread research.

Generally, an OLED is formed by sequentially stacking a first electrode, a hole transport layer, an emission layer, an electron transport layer, an insulating layer and a second electrode on a substrate under high vacuum, and the first and second electrodes may be transparent electrodes or metal electrodes. When a voltage is applied across the electrodes of the OLED, a hole from the first electrode is supplied to the emission layer through the hole transport layer and an electron from the second electrode is supplied to the emission layer through the electron transport layer. The hole and electron combine in the emission layer and light is emitted. The OLED has a high response speed and can be made thin and lightweight because it is self-emissive, not requiring a backlight, and can be driven at a low voltage. Also, it has excellent brightness and its display characteristics do not vary with viewing angle.

One method of manufacturing a full-color display using an OLED uses white light of a white OLED and a color filter which filters out red, green and blue (RGB) light. This method is not very efficient but has high productivity in mass-production of large OLEDs.

To fabricate a white OLED having a white emission property, materials emitting RGB, the primary 3 colors, or materials emitting light having a complementary color relationship, may be stacked. Accordingly, white OLEDs may be classified into three-wavelength white OLEDs and two-wavelength white OLEDs.

To be specific, the three-wavelength white OLED has a stacked structure of an anode, an emission layer and a cathode on a substrate, and the emission layer may be formed of RGB emitting materials. The three-wavelength white OLED using materials emitting the 3 primary colors has excellent color purity, but variable color stability due to energy transfer depending on an applied current or time because the RGB emitting materials are stacked. Consequently, when a hole blocking layer is inserted between the emitting materials, color stability may be enhanced. However in this case, the structure of the OLED becomes complicated, difficult to manufacture, and less efficient.

Another method for obtaining a three-wavelength OLED applies a fluorescent substance which can obtain green or red by energy transfer from blue to the exterior of a blue OLED. If there is a highly efficient blue OLED, a highly efficient white OLED may be obtained by this method, but a new element (i.e., a fluorescent substance) should be added therein.

The two-wavelength white OLED has a stacked structure of an anode, an emission layer and a cathode on a substrate, and the emission layer is formed of emitting materials (such as a combination of sky-blue and red, or blue and orange) having a complementary color relationship. As such, the two-wavelength white OLED is easily fabricated and has high efficiency compared to the three-wavelength white OLED. However, since the two-wavelength white OLED has a low green emission property compared to red and blue emission properties and poor color reproducibility, it is not proper for application fields that require high color purity and reproducibility (for example, flat panel displays, lighting, etc.).

### SUMMARY OF THE INVENTION

The present invention is directed to a white organic light emitting device (OLED) having enhanced efficiency, excellent color reproducibility, and a high color reproduction index (CRI), by employing a fluorescent or a phosphorescent substance that can obtain green or red emission by energy transfer.

One aspect of the present invention provides a white OLED including: a first electrode formed on a substrate; a hole transport layer formed on the first electrode; an emission layer formed on the hole transport layer; an electron transport layer formed on the emission layer; and an color control layer formed on at least one of the hole transport layer, the emission layer and the electron transport layer, and emitting green or red by energy transfer from the emission layer.

The emission layer may be formed of multiple layers including a blue emission layer and a red or green emission layer, or may be formed of a single layer including a blue emitting material and a red or green emitting material. The blue emission layer and the blue emitting material may be formed of a material having a band gap between 2.5 and 3.5 eV. The blue emission material may be one of DPVBi, NPB, perylene, etc. The red emission layer and the red emitting material may be formed of a material having a band gap between 1.7 and 2.2 eV. The red emitting material may be DCM, DCJTB, DADB, etc. The green emission layer and the green emitting material may be formed of a material having a band gap between 2.0 and 2.7 eV. The green emitting material may be Coumarin, C545T, etc.

A dopant concentration of the color control layer may be 0.1 to 10 wt %. When the emission layer emits blue and red, the color control layer may be doped with a dopant including a green fluorescent or phosphorescent substance having a band gap of 2.0 to 3.0 eV. When the emission layer emits blue and green, the color control layer may be doped with a dopant including a red fluorescent or phosphorescent substance having a band gap of 1.7 to 2.2 eV. A host injected into the color control layer may use a host material using for the hole transport layer or the blue emission of the emission layer. The color control layer may be formed to a thickness of 1 to 100 nm. The color control layer may be formed in at least one of lower and upper regions of the emission layer.

The white OLED may further include a hole blocking layer having a higher HOMO energy level than the emission layer formed between the electron transport layer and the emission layer. Also, the white OLED may further include a hole injection layer formed on the first electrode and an electron injection layer formed on the electron transport layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a side cross-sectional view of a white organic light emitting device (OLED) according to an exemplary embodiment of the present invention;

FIG. 2 is a side cross-sectional view of a white OLED according to another exemplary embodiment of the present invention;

FIG. 3 is a side cross-sectional view of a white OLED according to yet another exemplary embodiment of the present invention; and

FIG. 4 is an emission spectrum of a white OLED fabricated according to the present invention.

### DETAILED DESCRIPTION OF PREFERRED EMBODIMENTS

Hereinafter, exemplary embodiments of the present invention will be described in detail.

FIG. 1 is a side cross-sectional view of a white organic light emitting device (OLED) according to an exemplary embodiment of the present invention. Referring to FIG. 1, the white OLED 100 includes a substrate 110, a first electrode 120, a hole injection layer 130, a hole transport layer 140, an color control layer 150, an emission layer 160, an electron transport layer 170, an electron injection layer 180 and a second electrode 190.

To fabricate the white OLED according to the present invention, first, a substrate 110 is prepared. The substrate 110 may be formed of transparent glass, quartz or a flexible panel (for example, a plastic or metal thin film). The first electrode 120 is formed on the substrate 110. The first electrode 120 is an anode and is formed of one of several electrode materials (a transparent electrode and a metal electrode) depending on an emission type (top, bottom or dual emission), on the substrate 110. The first electrode 120 of the exemplary embodiment is formed of a material such as Indium Tin Oxide (ITO) or Indium Zinc Oxide (IZO) which has high transparency, high conductivity and a high work function to be used for dual emission. The first electrode 120 is formed by depositing and patterning a transparent electrode material on the substrate 110. Also, for the top emission, the first electrode 120 may be formed of a conductive material having reflectivity.

Next, a hole injection layer 130 is formed on the first electrode 120. The hole injection layer 130 is formed of a material helping hole injection (for example, 2-TNATA, MTDATA, CuPc, PEDOT:PSS, etc.), to a thickness of 10 nm to 50 nm, to easily inject a hole from the first electrode 120. A hole transport layer 140, which has high hole mobility and can easily transport holes, is formed on the hole injection layer 130. The hole transport layer 140 is formed of a material having high hole mobility such as N,N′-diphenyl-N,N′-bis-(3-methyl phenyl)-1,1′-biphenyl-4,4′-diamine (TPD) or 4,4′-bis [N-(1-naphthyl-1-)-N-phenyl-amino]-biphenyl (NPB). The hole transport layer 140 is formed to a thickness of 10 nm to 100 nm.

Referring to FIG. 1, an color control layer 150 is formed on the hole transport layer 140. The color control layer 150 may obtain green or red emission by energy transfer from an emission layer 160. For example, the color control layer 150 may change blue emission into green emission by energy transfer. The color control layer 150 uses a host material of the hole transport layer 140 or the emission layer 160, or a host material of an electron transport layer 170, and also uses an emitting material (a fluorescent or phosphorescent substance) emitting green or red by energy transfer as a dopant. In order to obtain a color which is not emitted by the emission layer 160, if the emission layer 160 emits blue and red, the color control layer 150 includes a green fluorescent or phosphorescent substance, and if the emission layer 160 emits blue and green, the color control layer 150 includes a red fluorescent or phosphorescent substance.

Here, a doping concentration of the green or red emitting material (a fluorescent or phosphorescent substance) is 0.1 to 10%. The thickness of the color control layer 150 may vary depending on an energy transfer degree of the doped emitting material and a desired shade of white, and is preferably 1 to 100 nm. Here, a green emitting material has a band gap of 2.0 to 3.0 eV, and a red emitting material may be formed of a material which has high fluorescent or phosphorescent efficiency and a band gap of 1.7 to 2.2 eV.

Then, the emission layer 160 formed on the color control layer 150 is formed of a material emitting blue and red, or blue and green. The emission layer 160 may be formed of two layers including blue and red emission layers or blue and green emission layers. Alternatively, it may be formed of one combined layer of blue and red emitting materials or blue and green emitting materials. The emission layer 160 is formed to a thickness of 10 to 500 nm in consideration of emission efficiency, and the emitting material constituting the emission layer 160 may have a concentration of 0.1 to 10%. The blue emitting material may be a material having a band gap of 2.5 to 3.5 eV, such as DPVBi, NPB and perylene. Also, the red emitting material may be a material having a band gap of 1.7 to 2.2 eV, such as DCM, DCJTB and DADB. The green emitting material may be a material having a band gap of 2.0 to 2.7 eV, such as Coumarin and C545T.

The electron transport layer (ETL) 170 is formed on the emission layer 160 to easily and effectively transport electrons to the emission layer 160. The electron transport layer 170 is formed of a material having high electron mobility such as tris(8-hydroxy quinoline)aluminum(Alq3) or 4,7-diphenyl-1,10-phenanthroline(BPhen). An electron injection layer (EIL) 180 is formed on the electron transport layer 170. The electron injection layer 180 may be formed of a material which can easily inject an electron from a second electrode 190, for example, an organic thin film such as 1,3,4-oxadiazole derivative (PBD), 4,7-diphenyl-1,10-phenanthroline(BPhen) or Li doped BPhen, or an inorganic thin film such as LiF, NaF, AlO and CsF.

The second electrode 190 is formed on the electron injection layer 180. The second electrode 190, a cathode, may be formed into whatever form a user wants to make on the electron injection layer 180. The second electrode 190 may be formed of various conductive materials depending on an emission type (top, bottom or dual emission) like the first electrode 120, for example, Al, Ag, LiAl, Mg/Al or Mg/Ag. The second electrode 190 may be formed in a transparent type having a thickness of 1 to 50 nm to obtain top emission.

In the above embodiment, the electron transport layer 170 is formed on the emission layer 160, but a hole blocking layer (not illustrated) having a higher HOMO energy level than the emission layer 160 may be further included between the electron transport layer 170 and the emission layer 160. In the above embodiment, the color control layer 150 is formed on the hole transport layer 140 and beneath the emission layer 160. Alternatively, the emission layer 160 is formed and then the color control layer 150 may be formed on the emission layer 160, or the emission layers may be formed on and beneath the color control layer 150, respectively.

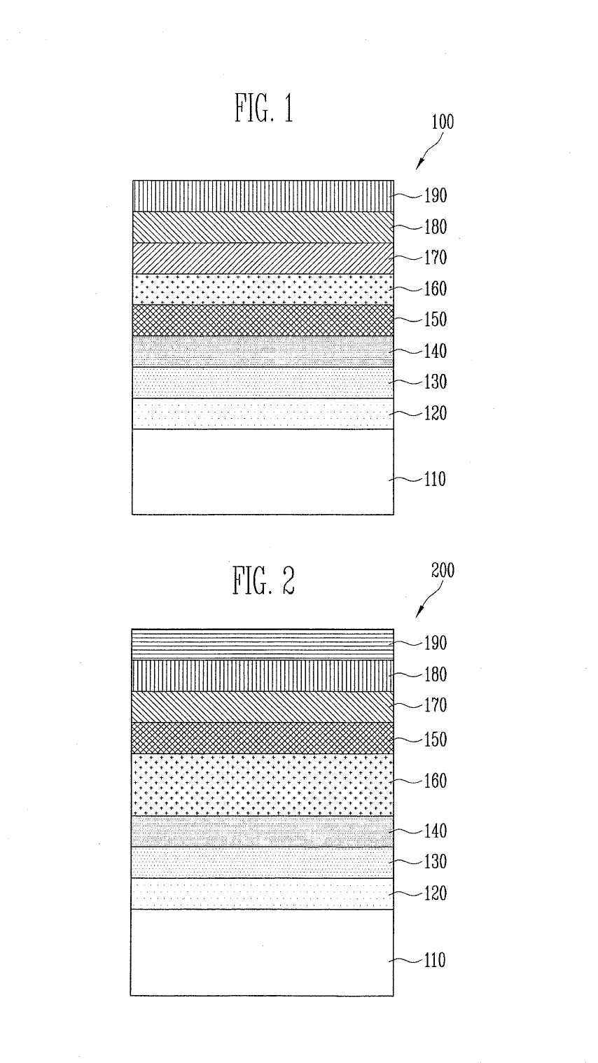

FIG. 2 is a side cross-sectional view of a white OLED according to another exemplary embodiment of the present invention. Referring to FIG. 2, the white OLED 200 includes a substrate 110 formed of transparent glass, quartz or plastic. A first electrode 120 is formed on a substrate 110 of the white OLED 200. A hole injection layer 130 is formed on the first electrode 120 to help hole injection, and a hole transport layer 140 is formed on the hole injection layer 130. An emission layer 160 is formed on the hole transport layer 140 and beneath an color control layer 150. An electron transport layer 170, an electron injection layer 180 and a second electrode 190 are sequentially stacked on the color control layer 150. Here, when the first and second electrodes 120 and 190 are formed of a transparent conductive metal, the OLED can emit light from its top and bottom, and when one of the first and second electrodes 120 and 190 is formed of a reflective metal, the OLED can emit light from its top or bottom.

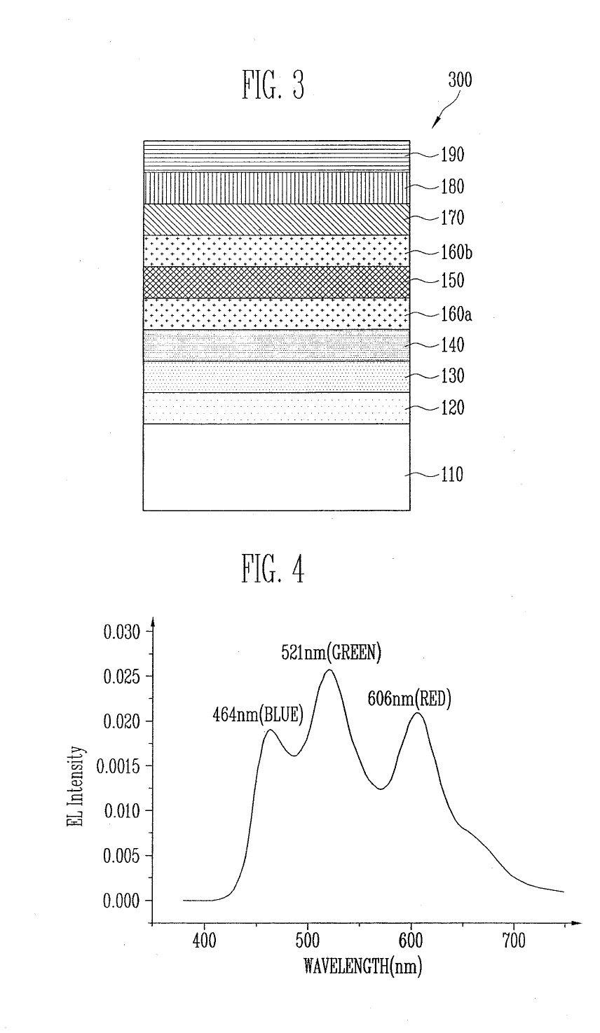

FIG. 3 is a side cross-sectional view of a white OLED according to yet another exemplary embodiment of the present invention. Referring to FIG. 3, the white OLED 300 includes a substrate 110 formed of transparent glass, quartz or plastic. A first electrode 120 is formed on the substrate 110 of the white OLED 300. A hole injection layer 130 helping hole injection and a hole transport layer 140 are sequentially formed on the first electrode 120. A first emission layer 160a and an color control layer 150 are sequentially formed on the hole transport layer 140. A second emission layer 160b, an electron transport layer 170, an electron injection layer 180 and a second electrode 190 are sequentially stacked on the color control layer 150.

The only differences between the white OLEDs 200 and 300 shown in FIGS. 2 and 3 and the OLED 100 shown in FIG. 1 are the stack thickness of the emission layers 160, 160a and 160b and locations of the color control layers 150. The OLEDs 100, 200, and 300 all include the same elements and are fabricated by the same method. Also, although not illustrated in any of the drawings, an color control layer may be formed in the hole transport layer or the electron transport layer.

FIG. 4 is an emission spectrum of a white OLED fabricated according to the present invention. The white OLED 100 shown in FIG. 1 was used to take the measurements plotted in FIG. 4. In the white OLED 100, the first electrode 120 was formed of ITO and the second electrode 190 was formed of Al. The hole injection layer 130 was formed of 2-TNATA to a thickness of 10 nm, and the hole transport layer 140 was formed of NPB to a thickness of 10 nm. The color control layer 150 formed on the hole transport layer 140 used NPB, a hole transport layer material, as a host and Coumarin, a green fluorescent substance, as a dopant, and was formed to a thickness of 1 nm. Here, the doping concentration of Coumarin was 1 wt %.

The emission layer 160 formed on the color control layer 150 was formed of a combined layer of blue and red emission layers. The blue emission layer used DPVBI as a host and DSA-amine as a dopant, and was formed to a thickness of 20 nm. Here, the dopant had a concentration of 5 wt %. The red emission layer used Alq as a host and DCJTB as a dopant, and was formed to a thickness of 6 nm. Here, the dopant had a concentration of 1 wt %. The electron transport layer 170 was formed of Alq to a thickness of 30 nm on the red emission layer of the emission layer 160. And, the electron injection layer 180 was formed of LiF to a thickness of 1 nm on the electron transport layer 170.

FIG. 4 is an emission (EL) spectrum graph of emission properties measured with a spectrometer (Minolta CS 1000) when a current of 10 mA/cm2 was applied between the first and second electrodes 120 and 190 at room temperature. As shown, at a blue emission wavelength of 464 nm, emission intensity was about 0.019 W/sr/m², at a green emission wavelength of 521 nm, emission intensity was about 0.026 W/sr/m², and at a red emission wavelength of 606 nm, emission intensity was about 0.022 W/sr/m². Here, color coordinates (x, y) were (0.34, 0.39). As a result, it was found that the white OLED 100 according to the present invention could obtain a three-wavelength white spectrum including green emission from a green fluorescent substance along with blue and red emission.

Table 1 shows properties of the three-wavelength white OLED used to obtain the measurements shown in FIG. 4.

TABLE 1

| | | | External | | |
|---|---|---|---|---|---|
| | | Current | quantum | Emission | Power |
| Brightness | Voltage | density | efficiency | efficiency | efficiency |
| (cd/m²) | (V) | (mA/cm²) | (%) | (cd/A) | (Im/W) |
| 130 | 5.0 | 1.2 | 5.3 | 11.0 | 7.6 |
| 1,500 | 6.5 | 12.2 | 5.9 | 12.3 | 6.6 |
| 77,000 | 12.0 | 1,170 | 3.2 | 6.6 | 1.9 |

Referring to Table 1, the brightness increased depending on current applied between both electrodes. When the brightness was 130 cd/m², 1500 cd/m² and 77000 cd/m², the emission efficiency was 11 cd/A, 12.3 cd/A and 6.6 cd/A, respectively. That is, the white OLED according to the present invention showed the highest emission efficiency (12.3 cd/A) at a brightness of 1500 cd/m², even though it is a three-wavelength white emitting device.

According to the experimental results of Table 1 and FIG. 4, a fluorescent substance capable of emitting green or red light can be inserted into the white OLED as the color control layer to obtain a highly efficient white OLED emitting RGB light. A liquid crystal display, a lighting board, etc. including a white backlight and a color filter may be easily implemented using such a white OLED.

As described above, a fluorescent substance which can obtain green or red by energy transfer from an emission layer is used as an color control layer, thereby providing a white OLED having high emission efficiency of red, green and blue, superior color reproducibility, and a high color reproduction index.

In addition, by using the white OLED, a liquid crystal display, a lighting board, etc. including a white backlight and a color filter can be easily realized.

While the present invention has been shown and described with reference to certain exemplary embodiments thereof, it will be understood by those skilled in the art that various changes in form and details may be made therein without departing from the spirit and scope of the present invention as defined by the appended claims.

What is claimed is:

1. A white organic light emitting device (OLED) comprising:
a first electrode formed on a substrate;
a hole transport layer formed on the first electrode;
an emission layer formed on the hole transport layer;
an electron transport layer formed on the emission layer; and
an color control layer formed on at least one of the hole transport layer, the emission layer and the electron transport layer, and emitting green or red by energy transfer from the emission layer.

2. The white OLED according to claim 1, wherein the emission layer is formed of multiple layers including a blue emission layer and a red emission layer or the blue emission layer and a green emission layer.

3. The white OLED according to claim 1, wherein the emission layer is formed of a single layer including a blue emitting material or a blue emitting material and a red emitting material or the blue emitting material and a green emitting material.

4. The white OLED according to claim 3, wherein the blue emitting material is formed of a material having a band gap between 2.5 and 3.5 eV.

5. The white OLED according to claim 4, wherein the material is one of DPVBi, NPB and perylene.

6. The white OLED according to claim 3, wherein the red emitting material is formed of a material having a band gap between 1.7 and 2.2 eV.

7. The white OLED according to claim 6, wherein the material is one of DCM, DCJTB and DADB.

8. The white OLED according to claim 2, wherein the green emission layer is formed of a material having a band gap between 2.0 and 2.7 eV.

9. The white OLED according to claim 8, wherein the material is one of Coumarin and C545T.

10. The white OLED according to claim 3, wherein the green emitting material is formed of a material having a band gap between 2.0 and 2.7 eV.

11. The white OLED according to claim 10, wherein the material is one of Coumarin and C545T.

12. The white OLED according to claim 1, wherein the color control layer has a dopant concentration of 0.1 to 10 wt %.

13. The white OLED according to claim 2, wherein when the emission layer emits blue light, the color control layer is doped with a dopant including a green and a red fluorescent or phosphorescent substance having a band gap between 1.7 and 3.0 eV.

14. The white OLED according to claim 3, wherein when the emission layer emits blue light, the color control layer is doped with a dopant including a green and a red fluorescent or phosphorescent substance having a band gap between 1.7 and 3.0 eV.

15. The white OLED according to claim 3, wherein when the emission layer emits blue and red light, the color control layer is doped with a dopant including a green fluorescent or phosphorescent substance having a band gap between 2.0 and 3.0 eV.

16. The white OLED according to claim 2, wherein when the emission layer emits blue and green light, the color control layer is doped with a dopant including a red fluorescent or phosphorescent substance having a band gap between 1.7 and 2.2 eV.

17. The white OLED according to claim 3, wherein when the emission layer emits blue and green light, the color control layer is doped with a dopant including a red fluorescent or phosphorescent substance having a band gap between 1.7 and 2.2 eV.

18. The white OLED according to claim 1, wherein a host injected into the color control layer uses a host material employed in the hole transport layer or the blue emission of the emission layer.

19. The white OLED according to claim 1, wherein the color control layer has a thickness of 1 to 100 nm.

20. The white OLED according to claim 1, wherein the color control layer is formed in at least one of lower and upper regions of the emission layer.

21. The white OLED according to claim 1, further comprising:
a hole blocking layer having a higher highest occupied molecular orbital (HOMO) energy level than the emission layer formed between the electron transport layer and the emission layer.

22. The white OLED according to claim 1, further comprising:
a hole injection layer formed on the first electrode; and
an electron injection layer formed on the electron transport layer.
